(19) United States
(12) Patent Application Publication
(10) Pub. No.: US 2010/0045389 A1
(43) Pub. Date: Feb. 25, 2010

(54) RING OSCILLATOR

(76) Inventors: PENGFEI HU, Shanghai (CN); ZHONGYUAN CHANG, Shanghai (CN)

Correspondence Address: HAYNES AND BOONE, LLP;IP Section, 2323 Victory Avenue, Suite 700, Dallas, TX, 75219, US

(21) Appl. No.: 12/195,301

(22) Filed: Aug. 20, 2008

(51) Int. Cl. H03K 3/03

(52) U.S. Cl. 331/57

(57) ABSTRACT

A ring oscillator is disclosed for generating one or more clock signals. In some embodiments, the ring oscillator includes a first set of n series coupled inverters, a second set of n series coupled inverters, a first reset switch configured to couple a last inverter of the first set of inverters to a first inverter of the second set of inverters and to generate a first signal edge, a second reset switch configured to couple a last inverter of the second set of inverters to a first inverter of the first set of inverters, and a cross-coupling circuit coupled between an output of an inverter of the first set of inverters to a corresponding output of an inverter of the second set of inverters. In some embodiments, 2n clock signals separated in phase by 360°/2n may be generated.

### BACKGROUND

1. Technical Field

The present invention relates to clock signal generation and, in particular, to a ring oscillator for generating clock signals.

2. Discussion of Related Art

Modern electronic devices often require coordinating the operation of digital circuits and systems. For example, two or more discrete circuits in a digital system may require that their operations be synchronized with each other in order to function properly. Accordingly, clock signals are widely used to coordinate and synchronize events in and between digital circuits and systems included in electronic devices.

A clock signal generally consists of a stable signal that oscillates between a high logic level and a low logic level in the form of a square wave having a 50% duty cycle. In some instances, a ring oscillator may be used to generate clock signals. The design and performance of many ring oscillators, however, can be sensitive to imperfections introduced during the manufacturing process. Such imperfections may also adversely affect power consumption.

Therefore, it is desirable to develop ring oscillator designs that provide for stable clock signal generation that is relatively unaffected by component imperfections introduced during the manufacturing process.

### SUMMARY

Consistent with some embodiments of the present invention, a ring oscillator includes a first set of n series coupled inverters; a second set of n series coupled inverters; a first reset switch configured to couple a last inverter of the first set of inverters to a first inverter of the second set of inverters and to generate a first signal edge; a second reset switch configured to couple a last inverter of the second set of inverters to a first inverter of the first set of inverters; a cross-coupling circuit coupled between an output of an inverter of the first set of inverters to a corresponding output of an inverter of the second set of inverters. In certain embodiments, the cross-coupling circuit may be configured to maintain differential signal levels at the output of an inverter of the first set of inverters and the corresponding output of an inverter of the second set of inverters.

Consistent with some embodiments of the present invention, a method of generating one or more clock signals using a ring oscillator includes generating a first signal edge at the input of a first inverter of a first set of series coupled inverters, the first set of inverters including n inverters; generating a second signal edge at the input of a first inverter of a second set of series coupled inverters, the second set of inverters including n inverters; and maintaining differential signal levels an output of an inverter of the first set of inverters and a corresponding output of an inverter of the second set of inverters; wherein and the first and second set of inverters are coupled such the input of the first inverter of the second set of inverters is coupled to an output of a last inverter of the first set of inverters and the input of the first inverter of the first set of inverters is coupled to an output of a last inverter of the second set of inverters.

Further embodiments and aspects of the invention are discussed with respect to the following figures, which are incorporated in and constitute a part of this specification.

### BRIEF DESCRIPTION OF THE DRAWINGS

FIG. 1 illustrates a schematic diagram of a ring oscillator consistent with some embodiments of the present invention.

FIG. 2 illustrates a schematic diagram of an exemplary inverter consistent with some embodiments of the present invention.

FIG. 3 illustrates a schematic diagram of a ring oscillator in reset mode consistent with some embodiments of the present invention.

FIG. 4 illustrates a schematic diagram of a ring oscillator after reset consistent with some embodiments of the present invention.

FIG. 5 illustrates an exemplary signal timing diagram of a ring oscillator after reset consistent with some embodiments of the present invention.

FIG. 6 illustrates a schematic diagram of an exemplary cross-coupling circuit that includes a pair of p-channel metal-oxide-semiconductor field effect (“pMOS”) transistors consistent with some embodiments of the present invention.

FIG. 7 illustrates a schematic diagram of an exemplary cross-coupling circuit that includes a pair of n-channel metal-oxide-semiconductor field effect (“nMOS”) transistors consistent with some embodiments of the present invention.

FIG. 8 illustrates a schematic diagram of an exemplary cross-coupling circuit that includes a pair of inverters consistent with some embodiments of the present invention.

In the figures, elements having the same designation have the same or similar functions.

### DETAILED DESCRIPTION

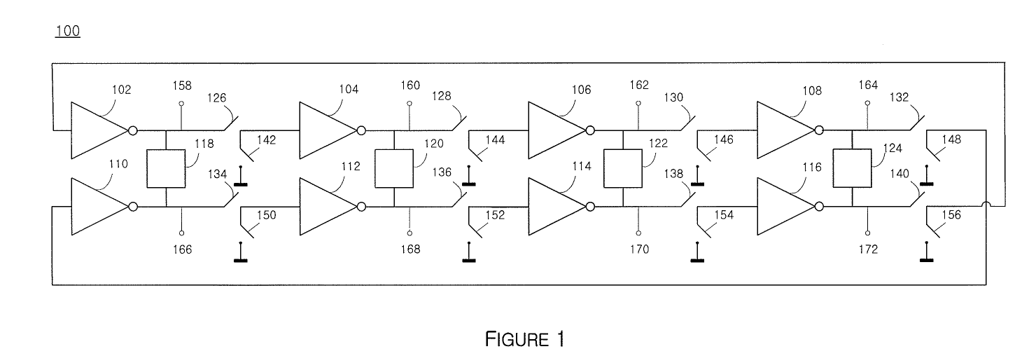

FIG. 1 illustrates a schematic diagram of a ring oscillator 100 consistent with some embodiments of the present invention. Ring oscillator 100 includes inverters 102-116, cross-coupling circuits 118-124, and switches 126-156. In the example illustrated in FIG. 1, ring oscillator 100 includes inverters 102-116, cross-coupling circuits 118-124, and switches 126-156. In some embodiments, ring oscillator 100 may include any even multiple of the number of inverters 102-116, cross-coupling circuits 118-114, and switches 126-156 illustrated in FIG. 1 (e.g., sixteen inverters, eight cross-coupling circuits, thirty-two switches, and the like).

The outputs of inverters 102-116, corresponding to circuit nodes 158-172, respectively, may be coupled to one of the terminals of switches 126-140, respectively. The inputs of inverters 104-116 and 102 may be coupled to the other terminals of switches 126-140, respectively. This configuration allows for the inputs of inverters 102-116 to be coupled to the outputs of inverters 104-116 and 102, respectively, when switches 126-140 are closed. For example, when switch 126 is closed, the output of inverter 102 is coupled to the input of inverter 104. In this manner, inverters 102-166 may be serially interconnected via switches 126-140 to form an inverter ring.

Switches 142-156 may be configured such that when they are closed, the inputs of inverters 104-116 and 102, respectively, are coupled to ground. Alternatively, in certain embodiments, the inputs of inverters 104-116 and 102 may be respectively coupled to a power terminal by switches 142-156. In some embodiments, switches 142-156 may be selectively closed (e.g., any one of switches 142-156 may be closed thereby coupling the input of their corresponding inverter to ground).

In some embodiments, switches 126 and 142 may be integrated into a single switch capable of coupling the inputs of inverter 104 to the output of inverter 102 or to ground. Switches 128 and 144, 130 and 146, 132 and 148, 134 and 150, 136 and 152, 138 and 154, and 140 and 156 may be similarly configured. Further, switches 126-156 may be implemented using any circuit(s) capable of performing these switching operations and/or any physical switching device.

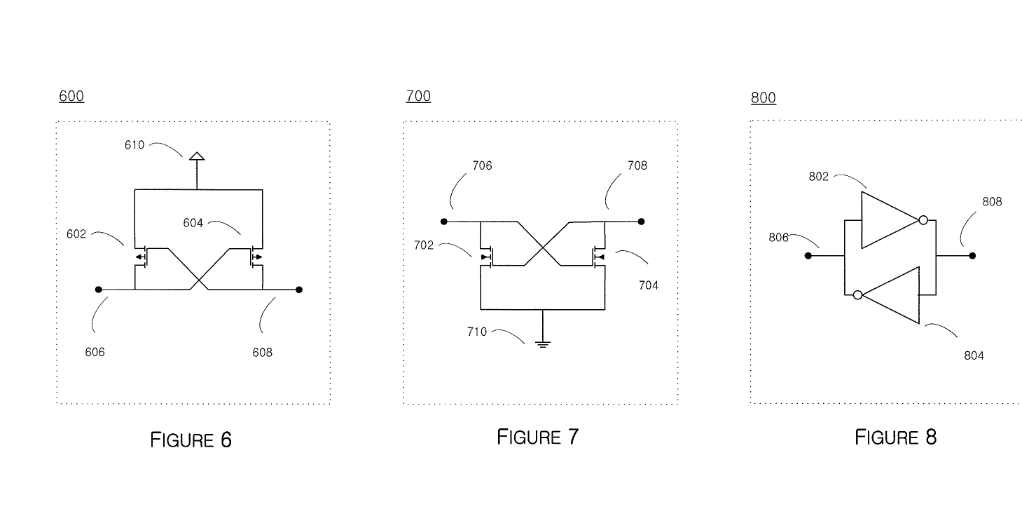

As illustrated in FIG. 1, cross-coupling circuit 118 may be coupled between circuit nodes 158 and 166 (i.e., between the outputs of inverters 102 and 110). Similarly, cross-coupling circuits 120-124 may be coupled between circuit nodes 160 and 168, 162 and 170, and 164 and 172, respectively. In this manner, cross-coupling circuits 118-124 couple a pair of ring oscillator 100 circuit nodes that have an equal number of inverters 102-116 between them in both directions. As discussed in more detail below, for example, in reference to FIG. 6, FIG. 7, and FIG. 8, cross-coupling circuits 118-124 function to counteract imperfections of ring oscillator 100, helping to make the oscillation of ring oscillator 100 sustainable.

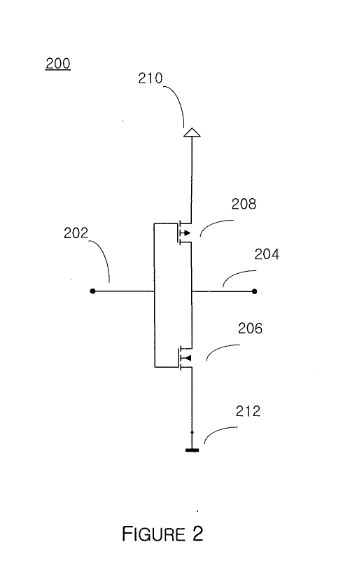

FIG. 2 illustrates a schematic diagram of an exemplary inverter 200 consistent with some embodiments of the present invention. Inverter 200 may be used as inverters 102-116 in ring oscillator 100 shown in FIG. 1. Inverter 200 utilizes complementary metal-oxide semiconductor field effect (“CMOS”) transistor technology. Alternatively, an inverter (e.g., a NOT gate) implemented using other technologies may be utilized as inverter 200 in ring oscillator 100. For example, n-channel metal-oxide-semiconductor field effect (“nMOS”) transistor technology, p-channel metal-oxide-semiconductor field effect (“pMOS”) transistor technology, an appropriate combination of NAND gate(s), an appropriate combination of NOR gate(s), and/or any other circuit that functions similarly may be utilized as inverter 200.

In the example illustrated in FIG. 2, inverter 200 includes input 202, output 204, nMOS transistor 206, pMOS transistor 208, power terminal (e.g., Vdd) 208, and ground terminal 212. Input 202 may be coupled to the gates of nMOS transistor 206 and pMOS transistor 208. The source of pMOS transistor 208 may be coupled to power terminal 208. Similarly, the source of nMOS transistor 206 may be coupled to ground terminal 212. The drain of nMOS transistor 206 and pMOS transistor 208 may be coupled to form inverter output 204.

Inverter 200 operates to invert the signal provided at its input 202 (e.g., performs logical negation of its input). For example, if a signal having a high logic value (i.e., a logical one value) is provided to the input 202 of inverter 200, output 204 of inverter 200 is set to a low logic level (i.e., a logical zero value). Similarly, if a signal having a low logic level is provided to the input 202 of inverter 200, output 204 of inverter 200 is set to a high logic level.

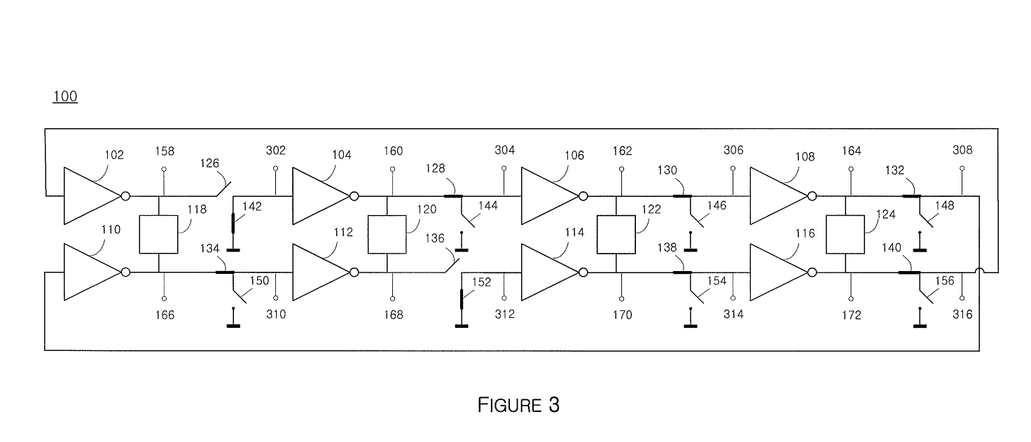

FIG. 3 illustrates a schematic diagram of the ring oscillator 100 shown in FIG. 1 in reset mode consistent with some embodiments of the present invention. In the reset mode shown in FIG. 3, switches 128-134 and 138-140 may be closed, thereby coupling the outputs of inverters 104-110 and 114-116 to the inputs of 106-112 and 116 and 102 respectively. Switches 144-150 and 154-156 may be opened such that the inputs of inverters 102, 106-112, and 116 are decoupled from ground. Switches 126 and 136 may be opened such that the inputs of inverters 104 and 114 are decoupled from the outputs of inverters 102 and 112. Finally, switches 142 and 152 may be closed, thereby coupling the inputs of inverters 103 and 114 to ground.

When configured in reset mode, ring oscillator 100 is in a non-oscillating steady state (e.g., the logical signal level values at circuit nodes 302-316 do not change). For example, in reset mode, circuit nodes 302, 306, 310, 312, and 316 may be set to a low logic level (i.e., ground or a logical one value) and may remain at low logic level as long as ring oscillator 100 remains in reset mode. Similarly, circuit nodes 304, 308, and 314 may be set to a high logic level and remain at a high logic level as long as ring oscillator 100 remains in reset mode.

The aforementioned operation of ring oscillator 100 in reset mode is described for illustrative purposes with respect to switches 126 and 136 being open, switches 132 and 152 being closed, switches 128-134 and 138-140 being closed, and switches 144-150 and 154-156 being open. Ring oscillator 100, however, may be placed in reset mode by orienting any two pairs of switches having an equal number of inverters between them in either direction, respectively, (e.g., switches 128 and 144 and switches 138 and 154) in the same manner described above with respect to switches 126 and 136 and switches 132 and 152, and orienting all other switches in the same manner as switches 128-134, 138-140, 144-150, and 154-156. In this manner, the two switches having an equal number of inverters between them in either direction, respectively, may be used to generate two propagating signal edges spaced evenly apart across the ring oscillator. In some embodiments, the ring oscillator may include only those switches necessary to generate a reset of the ring oscillator (e.g., generation of two propagating signal edges spaced evenly apart across the ring oscillator). Further, in some embodiments, ring oscillator 100 may be reset utilizing only those switches necessary to generate a single initial propagating signal edge around ring oscillator 100. Accordingly, in certain embodiments, ring oscillator 100 may use less switches than those illustrated in FIGS. 1 and 3-4.

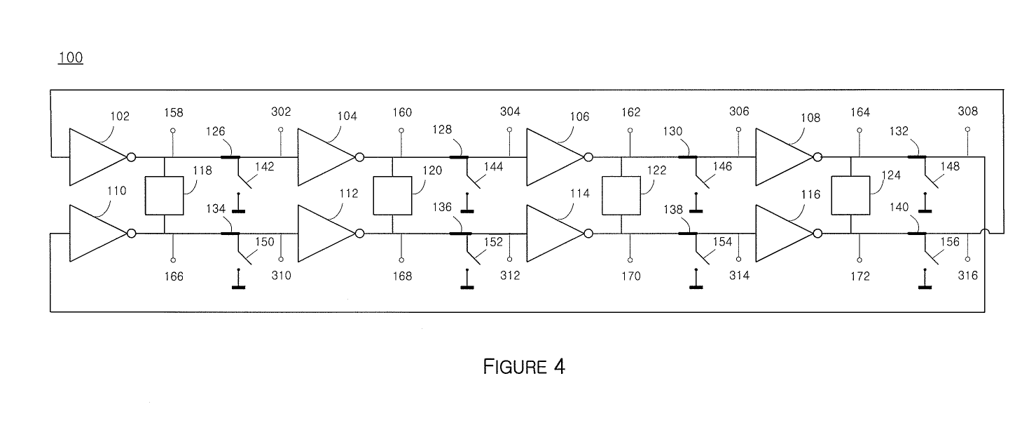

FIG. 4 illustrates a schematic diagram of the ring oscillator 100 shown in FIG. 1 after reset consistent with some embodiments of the present invention. After exiting reset mode as described in reference to FIG. 3, switches 126-140 may be closed, thereby coupling the outputs of inverters 102-116 to the inputs of inverters 104-116 and 102 (i.e., circuit nodes 302-316) respectively. Switches 142-156 may be opened such that the inputs of inverters 104-116 and 102 (i.e., circuit nodes 302-316) respectively are decoupled from ground. In this configuration, ring oscillator 100 after reset may be described as a chain of serially connected inverters 102-116 and cross-coupling circuits 118-124 that couple a pair of circuit nodes having an equal number of inverters between them in either direction, respectively.

By switching the ring oscillator 100 from the switch configuration in reset mode, as illustrated in FIG. 3, to the switch configuration after reset mode illustrated in FIG. 4, two signal edges begin to propagate around the chain of serially connected inverters 102-116 (e.g., ring of inverters), starting from nodes 302 and 312 respectively. After these signal edges propagate around ring oscillator 100 once, signal levels at circuit nodes 302-316 will subsequently oscillate between a high logic level and a low logic level at or near a frequency equal to the inverse of the combined delay time of inverters 102-116 (e.g., the period of the oscillation). Accordingly, eight clock signals each differing in phase by the delay time of one of inverters 102-116, denoted as t, and having a period of 8t may be extracted from ring oscillator 100 at circuit nodes 302-316.

Cross-coupling circuits 118-124 may be arranged to ensure that signal levels at circuit nodes having an equal number of inverters 102-116 between them in either direction remain differential. For example, with respect to FIG. 4, cross-coupling circuit 118 ensures that the signal levels at nodes 302 and 310 remain differential (e.g., out of phase by 180° or 4t). Further, cross-coupling circuits 118-124 help to ensure that the oscillation of signal levels in ring oscillator 100 remains sustainable and that the oscillating signals generated by ring oscillator 100 have a 50% duty cycle. In this manner, cross-coupling circuits 118-124 function to counteract imperfections of ring oscillator 100.

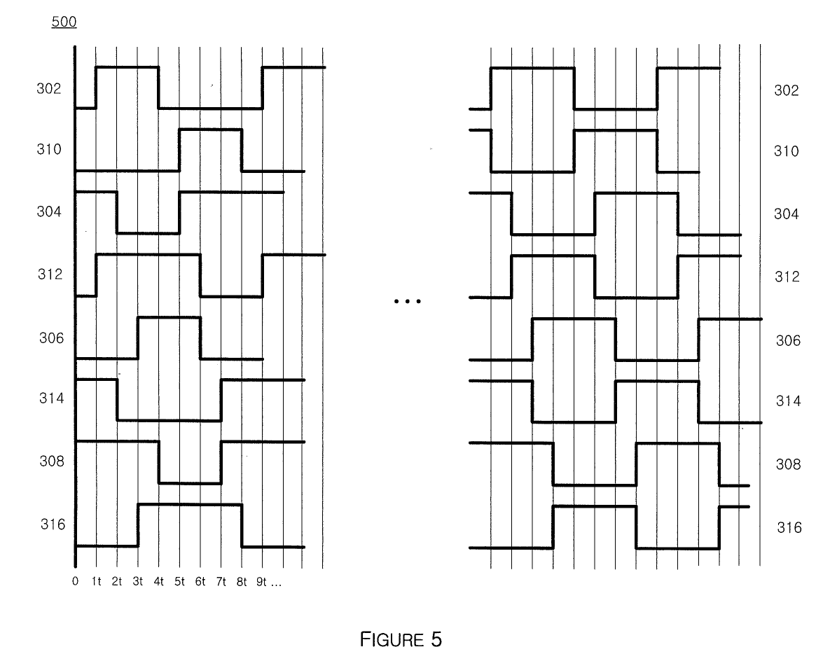

FIG. 5 illustrates an exemplary signal timing diagram 500 of a ring oscillator 100 after reset consistent with some embodiments of the present invention. Particularly, FIG. 5 illustrates the signal levels at circuit nodes 302-316 of ring oscillator 100 displayed in FIG. 3 starting after reset (i.e., time or ‘t’=0). At t=0, circuit nodes 302 and 312 are at a low logic level. After a time period t (i.e., t=t), circuit node 302 is set to a high logic level as the signal edge propagating around the chain of serially connected inverters generated by the closing of switch 126 after exiting reset reaches circuit node 302. In some embodiments, t may correspond to the time delay of one of inverters 102-118. In some embodiments, t may correspond to the average time delay of an inverter of inverters 102-118. For illustrative purposes, FIG. 5 is described in reference to the aforementioned signal edge as it propagates around the ring oscillator.

At t=2t, the propagating signal edge originating from circuit node 302 reaches circuit node 304, thereby causing the signal level at circuit node 304 to switch from a high logic level to a low logic level. At t=3t, this propagating signal edge reaches circuit node 306, thereby causing the signal level at circuit node 306 to switch from a low logic level to a high logic level. This signal edge continues to propagate around the ring oscillator, thereby causing the signal level at circuit nodes 308-316 to change their state at corresponding time intervals. After a period of 8t, this signal edge makes a complete trip around the ring oscillator, returning to circuit node 302, and continues to propagate around the ring oscillator in the same manner thereafter.

As the signal edge originating from circuit node 302 propagates around the ring oscillator, another signal edge originating from circuit node 312 also propagates around the chain of serially connected inverters generated by the closing of switch 136 after exiting reset. Similar corresponding state changes at nodes 308-316 occur as this signal edge propagates around the ring oscillator. After a period of 8t, this signal edge makes a complete trip around the ring oscillator, returning to circuit node 302, and continues to propagate around the ring oscillator in the same manner thereafter.

In the aforementioned manner, after the signal edges generated by reset propagate around the ring oscillator, signal levels at circuit nodes 302-316 will subsequently oscillate between a high logic level and a low logic level at or near a frequency equal to the inverse of the combined delay time denoted as of inverters 102-116 (e.g., the period of the oscillation), as illustrated by the ring oscillator signal levels shown on the right of FIG. 5. Accordingly, eight clock signals of the same frequency, each differing in phase by the delay time of one of inverters 102-116, denoted as t and having a period of 8t, may be extracted from ring oscillator 100 at circuit nodes 302-316.

Ideally, the oscillation described above will continue in perpetuity. However, due to mismatches between inverters 102-116 and/or other components in the ring oscillator as well as noise introduced into the propagating signals, the oscillation may die out over time as delays and/or noise caused by the imperfections can cause the duty cycle of the oscillating signal to wander to either 0 or 1. Accordingly, cross-coupling circuits 118-124 are configured to ensure that signal levels at circuit nodes having an equal number of inverters 102-116 between them in either direction remain differential, thereby ensuring that the oscillation of signal levels in the ring oscillator remains sustainable and have a 50% duty cycle. For example, cross-coupling circuit 118 ensures that the signal levels at nodes 302 and 310 remain differential (e.g., out of phase by 180° or 4t). In this manner, cross-coupling circuits 118-124 function to counteract imperfections of ring oscillator 100. Because any imperfections of ring oscillator 100 will generally be small, the relative sizes of cross-coupling circuits 118-124 may also be small, thus saving power. In some embodiments, cross-coupling circuits 188-124 may be designed such that their inverting functionality is strong enough to compensate for any imperfections of ring oscillator 100 without affecting the functionality of inverters 102-116.

FIG. 6 illustrates a schematic diagram of an exemplary cross-coupling circuit 600 that includes a pair of pMOS transistors 606-608 consistent with some embodiments of the present invention. Cross-coupling circuit 600 may be used as cross-coupling circuits 118-124 shown in FIG. 1. Cross-coupling circuit 600 includes pMOS transistors 602-604, cross-coupling circuit terminals 606-608, and power terminal 208. The sources of pMOS transistors 602-604 may be coupled to power terminal 610. The drain of pMOS transistor 602 is coupled to the gate of pMOS transistor 604 to form cross-coupling circuit terminal 606. Similarly, the drain of pMOS transistor 604 is coupled to the gate of pMOS transistor 602 to form cross-coupling circuit terminal 608. In certain embodiments, cross-coupling circuits 600 may be coupled between pairs of ring oscillator 100 circuit nodes 158-172 that have an equal number of inverters 102-116 between them in either direction.

Cross-coupling circuit 600 operates to keep the signal levels at cross-coupling circuit terminals 606-608 differential. For example, if a signal having a high logic value (e.g., a logical one value) is provided at cross-coupling circuit terminal 606, cross-coupling circuit 600 operates to ensure that the signal at cross-coupling terminal 608 is set to a low logic value (e.g., a logical zero value). Similarly, if a signal having a low logic value is provided at cross-coupling circuit terminal 606, cross-coupling circuit 600 operates to ensure that the signal at cross-coupling circuit terminal 608 is set to a high logic value.

FIG. 7 illustrates a schematic diagram of an exemplary cross-coupling circuit 700 that includes a pair of nMOS transistors 702-704 consistent with some embodiments of the present invention. Cross-coupling circuit 700 may be used as cross-coupling circuits 118-124 shown in FIG. 1. Cross-coupling circuit 700 includes nMOS transistors 702-704, cross-coupling circuit terminals 706-708, and ground terminal 710. The sources of nMOS transistors 702-704 may be coupled to ground terminal 710. The drain of nMOS transistor 702 is coupled to the gate of nMOS transistor 704 to form cross-coupling circuit terminal 706. Similarly, the drain of nMOS transistor 704 is coupled to the gate of nMOS transistor 702 to form cross-coupling circuit terminal 708. In certain embodiments, cross-coupling circuits 700 may be coupled between pairs of ring oscillator 100 circuit nodes 158-172 that have an equal number of inverters 102-116 between them in either direction.

Cross-coupling circuit 700 operates to keep the signal levels at cross-coupling circuit terminals 706-708 differential. For example, if a signal having a high logic value (e.g., a logical one value) is provided at cross-coupling circuit terminal 706, cross-coupling circuit 700 operates to ensure that the signal at cross-coupling terminal 708 is set to a low logic value (e.g., a logical zero value). Similarly, if a signal having a low logic value is provided at cross-coupling circuit terminal 706, cross-coupling circuit 700 operates to ensure that the signal at cross-coupling circuit terminal 708 is set to a high logic value.

FIG. 8 illustrates a schematic diagram of an exemplary cross-coupling circuit 800 that includes a pair of inverters 802-804 consistent with some embodiments of the present invention. Cross-coupling circuit 800 may be used as cross-coupling circuits 118-124 shown in FIG. 1. Cross-coupling circuit 800 includes inverters 802-804 and cross-coupling circuit terminals 806-808. As illustrated, the input of inverter 802 may be coupled with the output of inverter 804 to form cross-coupling circuit terminal 806. Similarly, the input of inverter 804 may be coupled to the output of inverter 802 to form cross-coupling circuit terminal 808. In certain embodiments, cross-coupling circuits 800 may be coupled between pairs of ring oscillator 100 circuit nodes 158-172 that have an equal number of inverters 102-116 between them in either direction.

Inverter 802 operates to invert the signal provided at cross-coupling circuit terminal 806. Inverter 804 operates to invert the signal provided at cross-coupling circuit terminal 808. For example, if a signal having a high logic value (e.g., a logical one value) is provided at cross-coupling circuit terminal 806, inverters 802 and 804 operate to ensure that cross-coupling circuit terminal 808 is set to a low logic value (e.g., a logical zero value). In this manner, cross-coupling circuit 800 operates to keep the signal levels at cross-coupling circuit terminals 806-808 differential.

In the preceding specification, various preferred embodiments have been described with reference to the accompanying drawings. It may, however, be evident that various modifications and changes may be made thereto, and additional embodiments may be implemented, without departing from the broader scope of the invention as set for in the claims that follow. The specification and drawings are accordingly to be regarded in an illustrative rather than restrictive sense.

What is claimed is:

1. A ring oscillator comprising:
a first set of n series coupled inverters;
a second set of n series coupled inverters;
a first reset switch configured to couple a last inverter of the first set of inverters to a first inverter of the second set of inverters and to generate a first signal edge;
a second reset switch configured to couple a last inverter of the second set of inverters to a first inverter of the first set of inverters; and
a cross-coupling circuit coupled between an output of an inverter of the first set of inverters to a corresponding output of an inverter of the second set of inverters.

2. The ring oscillator of claim 1, wherein the first reset switch comprises:
a first switch capable of coupling the input of the first inverter of the second set of inverters with the output of the last inverter of the first set of inverters; and
a second switch capable of coupling the input of the first inverter of the second set of inverters to ground.

3. The ring oscillator of claim 1, wherein the second reset switch comprises:
a third switch capable of coupling the input of the first inverter of the first set of inverters with the output of the last inverter of the second set inverters; and
a fourth switch capable of coupling the input of the first inverter of the first set of inverters to ground.

4. The ring oscillator of claim 1, wherein the cross-coupling circuit comprises:
a first pMOS transistor, the source of the first pMOS transistor being coupled to a power source;
a second pMOS transistor, the source of the second pMOS transistor being coupled to the power source;
a first cross-coupling circuit terminal, the first cross-coupling circuit terminal being coupled with the gate of the second pMOS transistor and the drain of the first pMOS transistor; and
a second cross-coupling circuit terminal, the second cross-coupling circuit terminal being coupled with the gate of the first pMOS transistor and the drain of the second pMOS transistor.

5. The ring oscillator of claim 1, wherein the cross-coupling circuit comprises:
a first nMOS transistor, the source of the first nMOS transistor being coupled to ground;
a second nMOS transistor, the source of the second nMOS transistor being coupled to ground;
a third cross-coupling circuit terminal, the third cross-coupling circuit terminal being coupled with the gate of the second nMOS transistor and the drain of the first nMOS transistor; and
a fourth cross-coupling circuit terminal, the fourth cross-coupling circuit terminal being coupled with the gate of the first nMOS transistor and the drain of the second nMOS transistor.

6. The ring oscillator of claim 1, wherein the cross-coupling circuit comprises:
a first cross-coupling inverter;
a second cross-coupling inverter;
a fifth cross-coupling circuit terminal, the fifth cross-coupling circuit terminal being coupled with an input of the first cross-coupling inverter and an output of the second cross-coupling inverter; and
a sixth cross-coupling circuit terminal, the sixth cross-coupling circuit terminal being coupled with an input of the second-cross coupling inverter and an output of the first cross-coupling inverter.

7. The ring oscillator of claim 1, wherein the cross-coupling circuit operates to maintain differential signal levels across the cross-coupling circuit.

8. The ring oscillator of claim 1, wherein the ring oscillator is configured to generate a plurality of clocks signals.

9. The ring oscillator of claim 8, wherein the plurality of clock signals include 2n clock signals extracted at the outputs of the inverters of the first and second set of inverters.

10. The ring oscillator of claim 9, wherein the 2n clock signals are separated in phase by 360°/2n.

11. The ring oscillator of claim 10, wherein the phase separation of the 2n clock signals is equal to the delay time of one of the inverters of the first or second set of inverters.

12. The ring oscillator of claim 8, wherein the plurality of clock signals have 50% duty cycles.

13. A method of generating one or more clock signals using a ring oscillator, the method comprising:
generating a first signal edge at the input of a first inverter of a first set of series coupled inverters, the first set of inverters including n inverters;
generating a second signal edge at the input of a first inverter of a second set of series coupled inverters, the second set of inverters including n inverters; and
maintaining differential signal levels at output of an inverter of the first set of inverters and a corresponding output of an inverter of the second set of inverters;
wherein and the first and second set of inverters are coupled such the input of the first inverter of the second set of inverters is coupled to an output of a last inverter of the first set of inverters and the input of the first inverter of the first set of inverters is coupled to an output of a last inverter of the second set of inverters.

14. The method of claim 13, wherein the one or more clock signals include 2n clock signals extracted at the outputs of the n inverters of the first set of inverters and the outputs of the n inverters of the second set of inverters.

15. The method of claim 14, wherein the one or more clock signals are separated in phase by 360°/2n.

16. The method of claim 15, wherein the phase separation of the 2n clock signals is equal to the delay time of one of the inverters of the first or second set of inverters.

17. The method of claim 13, wherein the one or more clock signals have 50% duty cycles.
